(19) United States
(12) Patent Application Publication
(10) Pub. No.: US 2012/0189834 A1
(43) Pub. Date: Jul. 26, 2012

(54) MATERIAL FOR SHIELDING AGAINST ELECTROMAGNETIC WAVES

(75) Inventor: Ludwig Goecke, Garbsen (DE)

(73) Assignee: HAGOTECH HOLDING GmbH, Diepenau (DE)

(21) Appl. No.: 13/390,152

(22) PCT Filed: Aug. 6, 2010
(86) PCT No.: PCT/DE10/75073

§ 371 Date: Mar. 29, 2012

(30) Foreign Application Priority Data
Aug. 11, 2009 (DE) 20 2009 010 801.5
Sep. 22, 2009 (DE) 20 2009 012 720.6

(51) Int. Cl. H05K 9/00; B32B 29/00; B32B 17/06; B32B 15/12

(52) U.S. Cl. 428/219; 428/457; 428/332; 428/334; 428/432

(57) ABSTRACT

A material for shielding against electromagnetic waves includes a flexible substrate including a paper. A coating includes zinc disposed on the substrate.

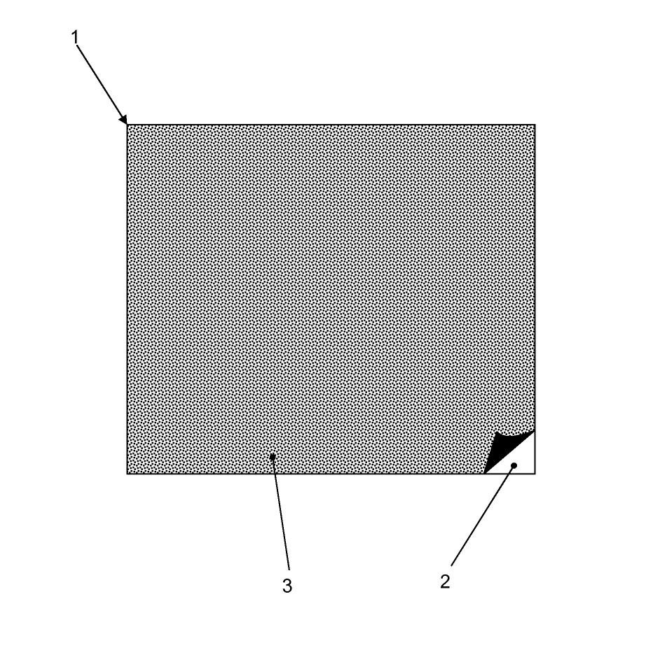

### CROSS REFERENCE TO PRIOR APPLICATIONS

This application is a U.S. National Phase application under 35 U.S.C. §371 of International Application No. PCT/DE2010/075073, filed on Aug. 6, 2010, and claims benefit to German Patent Application Nos. DE 20 2009 010 801.5, filed on Aug. 11, 2009 and DE 20 2009 012 720.6, filed on Sep. 22, 2009. The International Application was published in German on Feb. 17, 2011 as WO 2011/018084 under PCT Article 21 (2).

### FIELD

The invention relates to a material for shielding against electromagnetic waves. The invention further relates to a dimensionally stable material for shielding against electromagnetic waves.

### BACKGROUND

With an RFID chip or RFID transponder, information can be transmitted in a contactless manner over a short distance. Wireless identification systems of this type are widespread nowadays, and are used, for example, in personal access control in buildings or lift systems or for automation purposes and logistical purposes. In this context, they typically operate over a distance in the range from a few centimetres to several metres.

A typical RFID system basically consists of the following components: energy and data are transmitted between the read/write unit and the RFID chip either by inductive coupling or by coupling using electromagnetic waves. If the transponder draws the energy required for operation from the response field of the read/write unit, said transponder is referred to as “passive”.

By contrast, if the transponder has its own energy supply, it is an active transponder. Communicating by propagating electromagnetic waves makes much greater ranges possible.

A disadvantageous development in relation to the increasing use of RFID technology is in particular the loss of informational self-determination, since people often no longer have any control over which of their personal data are read or even changed.

Since 2006, German passports have also been provided with an RFID chip of this type, on which important data of the passport-holder are stored and with which wireless access is possible. Despite the increased data security due to encryption, misuse by third parties with adapted software and hardware is not reliably prevented.

In addition to official documents, in future more and more other documents, such as employee ID cards, health insurance cards, loyalty cards, etc., will be provided with this RFID chip, considerably increasing the risk of misuse by way of unauthorised access. Moreover, the very long validity period of some documents can mean that the RFID chips are not constantly being updated to the most recent prior art.

The most effective protection involves the wireless access to the RFID chip being suppressed by adapted shielding. This is achieved in practice by enclosing the RFID substrate in suitable metal housings made of copper, aluminium, zinc, or alloys of these metals.

DE 20 2005 013 139 U1 describes a protective document cover, for holding documents having an RFID chip, in which the material of the protective cover has an all-over metal coating or is covered with a metal layer adapted for wide-band shielding against electromagnetic waves. This provides that the dimensions of the shielding are only greater by a minimal amount than those of the document to be protected, and that the shielding is of a very low inherent weight whilst being very flexible and providing protection from soiling. This device can thus be carried together with the relevant document.

This involves plastics material films, preferably made of soft plastics material (polyethylene), which are provided with metal layers. These metal layers are either vapour-deposited or glued between the plastics material layers in the form of a metal foil. The covers themselves are bonded on three sides and only open at one narrow face in such a way that the document can be inserted and removed.

At a thickness of approximately 0.08 mm, under the most unfavourable circumstances the metal layer is permeable to the electromagnetic radiation of a very strong transmitter in direct proximity. However, the low transmitting power of the RFID chip means that any response from the RFID chip in the form of electromagnetic waves is completely suppressed.

Constructing a protective casing of this type from a non-conductive substrate layer on a woven textile, cardboard or a plastics material film has also been considered. However, resilient or extensible materials are found to be less adapted, since the coating applied thereto has limited durability, in particular abrasion resistance. On the other hand, the use of cardboard as an inflexible substrate significantly limits the possibilities of use.

### SUMMARY OF THE INVENTION

In an embodiment, the present invention provides a material for shielding against electromagnetic waves including a flexible substrate including a paper. A coating includes zinc disposed on the substrate.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

The single FIGURE shows is a schematic drawing of a material for shielding against electromagnetic waves.

### DETAILED DESCRIPTION

In an embodiment, an aspect of the invention provides a substrate, which is easy to manufacture yet durable, flexible and dimensionally stable and which opens up virtually any desired possibilities of use, with a corresponding coating.

In an embodiment, the invention provides a material for shielding against electromagnetic waves, for example, in the field of RFID technology, in particular in the form of a roll of material, comprising a coating, which has zinc as a significant material component, on a flexible substrate.

The fact that the substrate is a paper means that significant advantageous properties can be combined in a surprisingly simple manner. On the one hand, this results in the substrate having highly flexible properties and high tear resistance whilst also having a very low material thickness. The substrate can therefore be accommodated in a number of existing storage articles, in particular inserted as an intermediate layer, without spoiling the appearance thereof or influencing the external dimensions. At the same time, the paper has an extremely low resilience, which in combination with the surface roughness leads to extremely high durability and abrasion resistance. In particular, the mechanical cramping which can be achieved in the contact zone is not eliminated in part by relative movement of the coating and the substrate. Moreover, the paper, by contrast with thermoplastic plastics material substrates, is also highly thermally stable, and thus products equipped in this manner can also be exposed to high temperatures without any problems. Even soldered joints can be applied to the coating without damaging the substrate. The fact that the coating consists of zinc means that optimum protection from electromagnetic radiation is provided in all frequency ranges, in particular in the frequency range between 30 Hz and 10 GHz, and thus in the main field of application of RFID technology.

In this context, an embodiment in which the substrate has a weight of less than 100 g/m², but in particular of between 50 and 60 g/m², is found to be particularly promising. The specific product properties of the material created in this manner, in particular the good adhesion, the abrasion resistance and the flexibility, which in practice makes even creasing and folding possible without damaging the coating, mean that the material can be used for a number of applications. For example, RFID chips are protected from undesired access by a cover or packaging based on the material. This prevents the passive elements from being read or manipulated by a transponder.

Appropriate possibilities of use involve the material being formed as a blank for storage articles or garments or as a packaging material, for example. The material coated in this manner can therefore be incorporated into cases, purses, pockets or pieces of clothing of various embodiments.

Further, the material can be used as a shielding means for protection from any type of electrosmog, by covering emitting objects with the material. Conversely, virtually any objects can be effectively protected from the effect of external radiation. A particularly promising application of the material is therefore in telecommunications, as well as in medicine and in military technology. The material is particularly adapted for protecting sensitive products from electromagnetic radiation, and this also applies for example in aircraft. Thus, products can be protected from radiation simply by wrapping them in a material web. Drugs are just one example of this.

In principle, any known varieties and types of paper may be used as a substrate. For example, the substrate may be parchment or imitation parchment, transparent paper, sandwich paper or crepe paper, so as to achieve the desired properties, for example good temperature resistance or tear resistance.

In this context, a particularly advantageous embodiment of the invention is achieved in that the coating has a thickness of between 20 μm and 250 μm, in particular between 50 μm and 100 μm, it being possible not only for the coating thickness to be maintained precisely, but also for it to be variable, in particular to be adjustable so as to be different in some cases, so as to provide the adapted coating thickness for the respective purpose.

A particularly environmentally friendly material is provided in that the coating is applied to the substrate by arc spraying, providing a reliable and durable connection, in particular without adhesion promoters such as glue. This results in interlocking or mechanical cramping between the coating material and the substrate. This provides high abrasion resistance and a surface which is closed, without gaps. The material produced in this manner is found to be particularly environmentally friendly, since no solvent is required, and virtually pure zinc is applied to the substrate.

In an advantageous configuration, the connection between the substrate and the zinc layer is produced by a purely mechanical and thus perfectly environmentally friendly connection. In particular, no adhesives or other adhesion promoters are used. This applies to any substrates which are used, such as glass, all types of paper, card, wallpapers, all types of earthenware, plastics materials and the like.

A glass is used as a dimensionally stable substrate comprising the coating.

Various embodiments of the invention are possible. To further clarify the basic principle of the invention, one of these embodiments is shown in the drawing and described in the following. The drawing is a schematic drawing of a material 1 for shielding against electromagnetic waves, comprising a substrate 2 formed by a paper layer. A zinc coating 3 is applied thereto by arc spraying. On the one hand, this results in the material 1 having extremely flexible properties and high tear resistance whilst also having a very low material thickness, and therefore being able to be incorporated into a number of existing storage articles. On the other hand, at the same time the material 1 has an extremely low resilience, which in combination with the surface roughness leads to extremely high durability and abrasion resistance. The zinc coating 3 provides optimum protection from electromagnetic radiation in all frequency ranges, in particular in the field of RFID technology.

While the invention has been described with reference to particular embodiments thereof, it will be understood by those having ordinary skill the art that various changes may be made therein without departing from the scope and spirit of the invention. Further, the present invention is not limited to the embodiments described herein; reference should be had to the appended claims.

1-11. (canceled)

12: A material for shielding against electromagnetic waves comprising:
a flexible substrate including a paper; and
a coating including zinc disposed on the substrate.

13: The material as recited in claim 12, wherein the material is in a form of a roll of material.

14: The material as recited in claim 12, wherein the substrate has a weight of less than 100 g/m².

15: The material as recited in claim 14, wherein the weight is between 50 and 60 g/m².

16. The material as recited in claim 12, wherein the material is in a form of a blank for at least one of storage articles and garments.

17: The material as recited in claim 12, wherein the material is in a form of a blank for a packaging material.

18: The material as recited in claim 12, wherein the substrate includes one of a parchment and an imitation parchment.

19: The material as recited in claim 12, wherein the substrate includes a transparent paper.

20: The material as recited in claim 12, wherein a thickness of the coating is between 20 μm and 250 μm.

21: The material as recited in claim 20, wherein the thickness is between 50 μm and 100 μm.

22: The material as recited in claim 12, wherein the coating is arc-sprayed on the substrate.

23: The material as recited in claim 12, wherein a connection between the substrate and the coating is mechanical.

24: The material as recited in claim 23, wherein the connection includes no adhesives or adhesive promoters.

25: The material as recited in claim 12, wherein the electromagnetic waves have a frequency range from 30 Hz to 30 GHz.

26: A material for shielding against electromagnetic waves comprising:
a dimensionally stable substrate including a glass; and
a coating including, zinc disposed on the substrate.
